(19) United States
(12) Patent Application Publication
(10) Pub. No.: US 2025/0359331 A1
(43) Pub. Date: Nov. 20, 2025

(54) DRIVING SUBSTRATES AND DISPLAY PANELS

(71) Applicant: Shenzhen China Star Optoelectronics Semiconductor Display Technology Co., Ltd., Shenzhen, Guangdong (CN)

(72) Inventor: Chuanbao LUO, Shenzhen, Guangdong (CN)

(73) Assignee: Shenzhen China Star Optoelectronics Semiconductor Display Technology Co., Ltd., Shenzhen, Guangdong (CN)

(21) Appl. No.: 18/279,619

(22) PCT Filed: Jun. 15, 2023
(86) PCT No.: PCT/CN2023/100377

§ 371 Date: Jan. 3, 2025

(30) Foreign Application Priority Data
May 31, 2023 (CN) 202310647523.4

(51) Int. Cl. H10D 86/40; H10H 29/32

(52) U.S. Cl. CPC H10D 86/423; H10H 29/32

(57) ABSTRACT

Embodiments of the present disclosure provide a driving substrate and a display panel, in which an output electrode is used for electrically connecting a light-emitting device. An active layer includes a semiconductor part, a first conductive part, and a second conductive part. The first conductive part is connected to a side of the semiconductor part close to the output electrode, the second conductive part is connected to a side of the semiconductor part away from the output electrode, and the first conductive part is connected to the output electrode. A surface resistivity of the first conductive part is less than a surface resistivity of the second conductive part.

### TECHNICAL FIELD

The present disclosure relates to the field of display, in particular to driving substrates and display panels.

### BACKGROUND

Mini or micro light-emitting diode (MLED) display technology has entered an accelerated development stage in the past two years and can be used in the field of small and medium-sized high value-added display. Compared to an organic light-emitting diode (OLED) screen, the MLED display can perform better performances in terms of cost, contrast, high brightness, and lightweight appearance. In the MLED display technology, the backplane technology is the key technology.

In the research and practice of existing technology, the inventor of the present disclosure found that, due to the high current required for a light-emitting diode (LED) device, as the driving voltage of a driving thin film transistor increases, a high electric field is generated between a channel region and a drain region, which excites hot carriers. Further, the influence of hot carriers makes the threshold voltage (Vth) of the driving thin film transistor shift.

### SUMMARY

Embodiments of the present disclosure provide a driving substrate and a display panel, which can reduce a risk of the threshold voltage shift of a thin film transistor.

Embodiments of the present disclosure provide a driving substrate, which includes:
a substrate;
a first metal layer including an output electrode, in which the output electrode is used to electrically connect a light-emitting device;
a first insulation layer disposed on the first metal layer and covering the substrate;
an active layer disposed on the first insulation layer and including a semiconductor part, a first conductive part, and a second conductive part, in which the first conductive part is connected to a side of the semiconductor part close to the output electrode, the second conductive part is connected to a side of the semiconductor part away from the output electrode, and the first conductive part is connected to the output electrode; a surface resistivity of the first conductive part is less than a surface resistivity of the second conductive part;
a second insulation layer disposed on the semiconductor part;
at least one gate disposed on the second insulation layer and overlapped with the semiconductor part; and
a second metal layer including an input electrode, in which the input electrode is connected to the second conductive part, and the input electrode, the output electrode, the active layer, and the gate are used to form a thin film transistor.

Optionally, in some embodiments of the present disclosure, a concentration of a doped ion in the first conductive part may be greater than a concentration of a doped ion in the second conductive part.

Optionally, in some embodiments of the present disclosure, a material of the first conductive part may include a metal oxide and the doped ion, and the doped ion may be doped in the metal oxide; a material of the second conductive part may include at least the metal oxide.

Optionally, in some embodiments of the present disclosure, the material of the second conductive part may include the doped ion.

Optionally, in some embodiments of the present disclosure, the at least one gate may include a first gate and a second gate, the first gate may be disposed on the second insulation layer, the second gate may be disposed in a same layer as the output electrode, and the second gate may be disposed between the first insulation layer and the substrate; and

the semiconductor part may include a channel, the first gate may cover the channel, and the second gate may be disposed partially overlapping with the channel; a part of the channel overlapping with the second gate may be connected to the first conductive part, and a part of the channel not overlapping with the second gate may be connected to the second conductive part.

Optionally, in some embodiments of the present disclosure, a length of the part of the channel overlapping with the second gate may account for one-fourth to one-half of a length of the channel in a direction from the first conductive part towards the second conductive part.

Optionally, in some embodiments of the present disclosure, the first conductive part, the semiconductor part, and the second conductive part may be disposed in a same layer and integrally formed.

Optionally, in some embodiments of the present disclosure, the first conductive part and the second conductive part may be disposed in a same layer and spaced apart, the semiconductor part may include a first lap-joint part and a second lap-joint part, the first lap-joint part may be connected to a side of the first conductive part away from the substrate, and the second lap-joint part may be connected to a side of the second conductive part away from the substrate; an end of the channel may be connected to the first lap-joint part and the first conductive part, and another end of the channel may be connected to the second lap-joint part and the second conductive part.

Optionally, in some embodiments of the present disclosure, the output electrode may be overlapped with the active layer.

Optionally, in some embodiments of the present disclosure, a part of the first conductive part overlapping with the first lap-joint part may have a first resistance value, a part of the first conductive part not overlapping with the first lap-joint part may have a second resistance value, and the first resistance value may be greater than the second resistance value.

Optionally, in some embodiments of the present disclosure, the driving substrate may include a third insulation layer, and the third insulation layer may be disposed on the at least one gate and cover the active layer and the first insulation layer; the second metal layer may be disposed on the third insulation layer; and
the input electrode may block the semiconductor part and the second conductive part, in a pattern of an orthographic projection of the driving substrate, the first conductive part may be at least partially disposed outside the input electrode.

Accordingly, embodiments of the present disclosure further provide a display panel, which includes a light-emitting device and the driving substrate as described in any of the above-mentioned embodiments. The light-emitting device is disposed on the driving substrate, and an output electrode is provided to be electrically connected to the light-emitting device. The driving substrate includes:
a substrate;
a first metal layer including an output electrode, in which the output electrode is used to electrically connect a light-emitting device;
a first insulation layer disposed on the first metal layer and covering the substrate;
an active layer disposed on the first insulation layer and including a semiconductor part, a first conductive part, and a second conductive part, in which the first conductive part is connected to a side of the semiconductor part close to the output electrode, the second conductive part is connected to a side of the semiconductor part away from the output electrode, and the first conductive part is connected to the output electrode; a surface resistivity of the first conductive part is less than a surface resistivity of the second conductive part;
a second insulation layer disposed on the semiconductor part;
at least one gate disposed on the second insulation layer and overlapped with the semiconductor part; and
a second metal layer including an input electrode, in which the input electrode is connected to the second conductive part, and the input electrode, the output electrode, the active layer, and the gate are used to form a thin film transistor.

Optionally, in some embodiments of the present disclosure, a concentration of a doped ion in the first conductive part may be greater than a concentration of a doped ion in the second conductive part.

Optionally, in some embodiments of the present disclosure, a material of the first conductive part may include a metal oxide and the doped ion, and the doped ion may be doped in the metal oxide; a material of the second conductive part may include at least the metal oxide.

Optionally, in some embodiments of the present disclosure, the material of the second conductive part may include the doped ion.

Optionally, in some embodiments of the present disclosure, the at least one gate may include a first gate and a second gate, the first gate may be disposed on the second insulation layer, the second gate may be disposed in a same layer as the output electrode, and the second gate may be disposed between the first insulation layer and the substrate; and

the semiconductor part may include a channel, the first gate may cover the channel, and the second gate may be disposed partially overlapping with the channel; a part of the channel overlapping with the second gate may be connected to the first conductive part, and a part of the channel not overlapping with the second gate may be connected to the second conductive part.

Optionally, in some embodiments of the present disclosure, a length of the part of the channel overlapping with the second gate may account for one-fourth to one-half of a length of the channel in a direction from the first conductive part towards the second conductive part.

Optionally, in some embodiments of the present disclosure, the first conductive part, the semiconductor part, and the second conductive part may be disposed in a same layer and integrally formed.

Optionally, in some embodiments of the present disclosure, the first conductive part and the second conductive part may be disposed in a same layer and spaced apart, the semiconductor part may include a first lap-joint part and a second lap-joint part, the first lap-joint part may be connected to a side of the first conductive part away from the substrate, and the second lap-joint part may be connected to a side of the second conductive part away from the substrate; an end of the channel may be connected to the first lap-joint part and the first conductive part, and another end of the channel may be connected to the second lap-joint part and the second conductive part.

Optionally, in some embodiments of the present disclosure, the output electrode may be overlapped with the active layer.

Optionally, in some embodiments of the present disclosure, a part of the first conductive part overlapping with the first lap-joint part may have a first resistance value, a part of the first conductive part not overlapping with the first lap-joint part may have a second resistance value, and the first resistance value may be greater than the second resistance value.

Optionally, in some embodiments of the present disclosure, the driving substrate may include a third insulation layer, and the third insulation layer may be disposed on the at least one gate and cover the active layer and the first insulation layer; the second metal layer may be disposed on the third insulation layer; and
the input electrode may block the semiconductor part and the second conductive part, in a pattern of an orthographic projection of the driving substrate, the first conductive part may be at least partially disposed outside the input electrode.

### Beneficial Effects

the driving substrate of the embodiments includes the substrate, the first metal layer, the first insulation layer, the active layer, the second insulation layer, the at least one gate, and the second metal layer. The first metal layer includes the output electrode for electrically connecting the light-emitting device. The first insulation layer is disposed on the first metal layer and covers the substrate. The active layer is disposed on the first insulation layer and includes the semiconductor part, the first conductive part, and the second conductive part. The first conductive part is connected to a side of the semiconductor part close to the output electrode, the second conductive part is connected to a side of the semiconductor part away from the output electrode, and the first conductive part is connected to the output electrode. The surface resistivity of the first conductive part is less than the surface resistivity of the second conductive part. The second insulation layer is disposed on the semiconductor part. The gate is disposed on the second insulation layer and overlapping with the semiconductor part. The second metal layer includes the input electrode connected to the second conductive part. The input electrode, the output electrode, the active layer, and the gate are used to form the thin film transistor.

Due to the fact that the surface resistivity of the first conductive part is less than the surface resistivity of the second conductive part, the resistance of part of the active layer close to the output electrode is less than the resistance of part of the active layer close to the input electrode, which decreases the voltage drop of part of the active layer close to the output electrode, thereby reducing the impact of hot carriers on the threshold voltage.

### DESCRIPTION OF DRAWINGS

FIG. 1 is a schematic structural diagram of a driving substrate according to a first embodiment of the present disclosure.

FIG. 2 is a schematic diagram of step B11 in a preparation process of the driving substrate according to the first embodiment of the present disclosure.

FIG. 3 is a schematic diagram of step B12 in the preparation process of the driving substrate according to the first embodiment of the present disclosure.

FIG. 4 is a schematic diagram of step B13 in the preparation process of the driving substrate according to the first embodiment of the present disclosure.

FIG. 5 is a schematic diagram of step B14 in the preparation process of the driving substrate according to the first embodiment of the present disclosure.

FIG. 6 is a schematic structural diagram of a driving substrate according to a second embodiment of the present disclosure.

FIG. 7 is a schematic structural diagram of a driving substrate according to a third embodiment of the present disclosure.

FIG. 8 is a schematic diagram of step B21 in a preparation process of the driving substrate according to the third embodiment of the present disclosure.

FIG. 9 is a schematic diagram of step B22 in the preparation process of the driving substrate according to the third embodiment of the present disclosure.

FIG. 10 is a schematic diagram of step B23 in the preparation process of the driving substrate according to the third embodiment of the present disclosure.

FIG. 11 is a schematic diagram of step B24 in the preparation process of the driving substrate according to the third embodiment of the present disclosure.

FIG. 12 is a schematic structural diagram of a display panel according to one or more embodiments of the present disclosure.

### DETAILED DESCRIPTION OF EMBODIMENTS

The following will provide a clear and complete description of the technical solutions in the embodiments of this application in conjunction with the accompanying drawings. Apparently, the described embodiments are only a part of the embodiments of the present disclosure, not all of them. Based on the embodiments of the present disclosure, all other embodiments obtained by those skilled in the art without creative effort fall within the protection scope of the present disclosure. In addition, it should be understood that specific embodiments described herein are only used for the purpose of demonstrating and explaining the present disclosure and are not intended to limit the present disclosure. In the present disclosure, the directional terms used, such as “up” and “down”, generally refer to up and down positions of the device in actual use or working state, specifically the surface directions in the drawings, unless otherwise specified, such as terms “inside” and “outside”, are specific to the contour of the device.

Embodiments of the present disclosure provide a driving substrate and a display panel, which will be described in detail below. It should be noted that the description order of the following embodiments does not serve as a limitation on the preferred order of the embodiments.

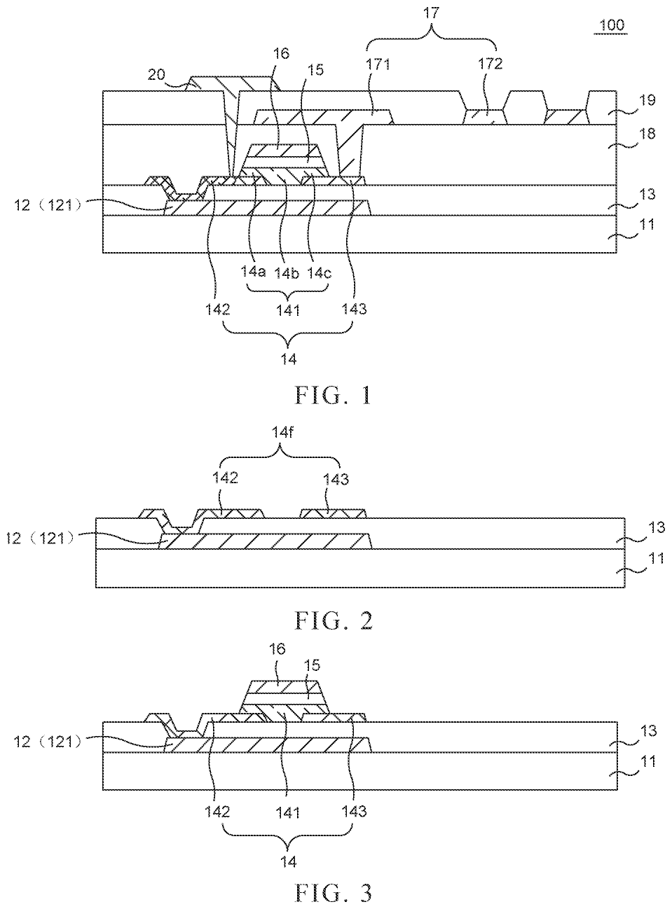

Referring to FIG. 1, a first embodiment of the present disclosure provides a driving substrate 100, which includes a substrate 11, a first metal layer 12, a first insulation layer 13, an active layer 14, a second insulation layer 15, a gate 16, and a second metal layer 17.

The first metal layer 12 includes an output electrode 121 for electrically connecting a light-emitting device. The first insulation layer 13 is disposed on the first metal layer 12 and covers the substrate 11. The active layer 14 is disposed on the first insulation layer 13.

The active layer 14 includes a semiconductor part 141, a first conductive part 142, and a second conductive part 143. The first conductive part 142 is connected to a side of the semiconductor part 141 close to the output electrode 121, the second conductive part 143 is connected to a side of the semiconductor part 141 away from the output electrode 121, and the first conductive part 142 is connected to the output electrode 121. A surface resistivity of the first conductive part 142 is less than a surface resistivity of the second conductive part 143.

The second insulation layer 15 is disposed on the semiconductor part 141. The gate 16 is disposed on the second insulation layer 15 and overlapping with the semiconductor part 141. The second metal layer 17 includes an input electrode 171 connected to the second conductive part 143. The input electrode 171, the output electrode 121, the active layer 14, and the gate 16 is used to form a thin film transistor.

Due to the fact that the surface resistivity of the first conductive part 142 is less than the surface resistivity of the second conductive part 143, the resistance of the part of the active layer 14 close to the output electrode 121 is less than the resistance of the part of the active layer 14 close to the input electrode 171, which decreases the voltage drop of the part of the active layer 14 close to the output electrode 121, thereby reducing the impact of hot carriers on the threshold voltage.

It should be noted that, in the active layer 14, when the channel is divided in half, the total resistance of the first conductive part 142 and one half of the channel is set as a first total resistance, and the total resistance of the second conductive part 143 and the other half of the channel is set as a second total resistance. The influence of hot carriers on the threshold voltage of the thin film transistor can be reduced when the first total resistance is less than the second total resistance.

Optionally, one of the input electrode 171 and the output electrode 121 is a source, and the other is a drain. In the embodiments, the input electrode 171 being the source and the output electrode 121 being the drain are taken for an example for explanation.

When the resistance of the region of the active layer 14 close to the drain is less than the resistance of the region of the active layer 14 close to the source, the voltage drop near the drain region can be reduced, thereby reducing the impact of the hot carriers on the threshold voltage of the thin film transistor.

Optionally, a material of the substrate 11 may include one of glass, sapphire, silicon, silicon dioxide, polyethylene, polypropylene, polystyrene, polylactic acid, polyethylene terephthalate, polyethylene naphthalate, polycarbonate, polyethersulfone, aromatic fluorotoluene containing polyarylester, polycyclic olefin, polyimide, and polyurethane.

Optionally, the first metal layer 12 is made of metal selected from chromium, copper, aluminum, gold, silver, zinc, molybdenum, tantalum, titanium, tungsten, manganese, nickel, iron, cobalt, alloy of any of the above-mentioned metal or alloy containing any of the above-mentioned metal. Moreover, the first metal layer 12 may be a single layer structure or a stacked structure of two or more layers.

Optionally, the output electrode 121 is disposed to be overlapping with the active layer 14. Since the output electrode 121 blocks the active layer 14, the risk of light radiation to the active layer 14 can be reduced, and the stability of the thin film transistor is improved.

Optionally, both of the first insulation layer 13 and the second insulation layer 15 may be formed by multiple inorganic layers stacked in an alternate manner. For example, both of the first insulation layer 13 and the second insulation layer 15 may be a double layer formed by stacking inorganic layers including at least one of silicon oxide, silicon nitride, silicon nitride, aluminum oxide, magnesium oxide, and titanium oxide, or multiple layers formed by alternately stacking inorganic layers including at least one of silicon oxide, silicon nitride, silicon nitride, aluminum oxide, magnesium oxide, and titanium oxide. However, the present disclosure is not limited thereto. Both of the first insulation layer 13 and the second insulation layer 15 may be formed as a single inorganic layer including the above-mentioned insulation materials.

Optionally, in the active layer 14, the first conductive part 142 and the second conductive part 143 are disposed in the same layer and spaced apart. The semiconductor part 141 includes a first lap-joint part 14a, a channel 14b, and a second lap-joint part 14c. The first lap-joint part 14a is connected to a side of the first conductive part 142 away from the substrate 11. The second lap-joint part 14c is connected to a side of the second conductive part 143 away from the substrate 11. One end of the channel 14b is connected to the first lap-joint part 14a and the first conductive part 142, and the other end of channel 14b is connected to the second lap-joint part 14c and the second conductive part 143.

The material of the first conductive part 142 and the second conductive part 143 includes a metal oxide with lower resistivity, such as ITO, IZO, or the like.

A material of the semiconductor part 141 may include at least one of indium gallium zinc oxide, indium zinc oxide, zinc tin oxide, indium gallium oxide, indium tin oxide, indium zirconium oxide, indium zirconium zinc oxide, indium zirconium tin oxide, indium zirconium gallium oxide, indium aluminum oxide, indium zinc aluminum oxide, indium tin aluminum oxide, indium aluminum gallium oxide, indium tantalum oxide, indium tantalum zinc oxide, indium tantalum tin oxide, indium tantalum gallium oxide, indium germanium oxide, indium germanium zinc oxide, indium germanium tin oxide, indium germanium gallium oxide, titanium indium zinc oxide, and hafnium indium zinc oxide.

Optionally, a concentration of a doped ion in the first conductive part 142 is greater than a concentration of a doped ion in the second conductive part 143.

It can be understood that, during an ion implantation process, the higher the concentration of the injected doped ion, the higher the conductivity. Since the concentration of the doped ion in the first conductive part 142 is greater than the concentration of the doped ion in the second conductive part 143, the resistance value of the first conductive part 142 is less than the resistance value of the second conductive part 143, which can reduce the voltage drop near the drain region.

Optionally, the material of the first conductive part 142 includes a metal oxide and the doped ion, and the doped ion is doped in the metal oxide. The material of the second conductive part 143 includes at least a metal oxide.

In this embodiment, the material of the second conductive part 143 may include only a metal oxide. That is, the second conductive part 143 does not require the ion doping.

When both of the first conductive part 142 and the second conductive part 143 include the same metal oxide, only the first conduction part 142 may be ion-doped, so that the surface resistivity of the first conduction part 142 is less than the surface resistivity of the second conduction part 143.

In some embodiments, the material of the second conductive part 143 further includes the doped ion. That is, the second conductive part 143 can be ion-doped to improve the conductivity of the second conductive part 143, but the concentration of the doped ion in the second conductive part 143 is less than the concentration of the doped ion in the first conductive part 142.

Optionally, the part of the first conductive part 142 that overlaps with the first lap-joint part 14a has a first resistance value, the part of the first conductive part 142 that does not overlap with the first lap-joint part 14a has a second resistance value, and the first resistance value is greater than the second resistance value.

That is, the part of the first conductive part 142 that overlaps with the first lap-joint part 14a is not doped with the doped ion, and the part of the first conductive part 142 that does not overlap with the first lap-joint part 14a is doped with the doped ion, so that the first resistance value can be greater than the second resistance value.

Because both of the resistance value of the part of the first conductive part 142 that overlaps with the first lap-joint part 14a and the resistance value of the part of the second conductive part 143 that overlaps with the second lap-joint part 14c are less than the resistance value of the semiconductor part 141, and the first conductive part 142 and the second conductive part 143 are lap-jointed with the semiconductor part 141. That is, the first conductive part 142 and the second conductive part 143 due to their relationship with the semiconductor part 141 help narrow the length of the channel and improve the electron mobility.

Moreover, because the resistance value of the part of the first conductive part 142 that overlaps with the first lap-joint part 14a is less than the resistance value of the semiconductor part 141, the voltage drop near the drain region can further be reduced, which reduces the influence of the hot carriers on the threshold voltage of the thin film transistor.

Optionally, the surface resistivity of the part of the first conductive part 142 that overlaps with the first lap-joint part 14a ranges from 3 times to 10 times than the surface resistivity of the part of the first conductive part 142 that does not overlap with the first lap-joint part 14a.

For example, the surface resistivity of the part of the first conductive part 142 that overlaps with the first lap-joint part 14a may range from 10 Ω/sq to 100 Ω/sq, such as 10 Ω/sq, 20 Ω/sq, 30 Ω/sq, 40 Ω/sq, 50 Ω/sq, 60 Ω/sq, 70 Ω/sq, 80 Ω/sq, 90 Ω/sq, or 100 Ω/sq.

The surface resistivity of the part of the first conductive part 142 that does not overlap with the first lap-joint part 14a may range from 1 Ω/sq to 10 Ω/sq, such as 1 Ω/sq, 2 Ω/sq, 3 Ω/sq, 4 Ω/sq, 5 Ω/sq, 6 Ω/sq, 7 Ω/sq, 8 Ω/sq, 9 Ω/sq, or 10 Ω/sq.

Optionally, an area of the part of the first conductive part 142 that overlaps with the first lap-joint part 14a is greater than an area of the part of the second conductive part 143 that overlaps with the second lap-joint part 14c, further reducing the influence of the hot carriers on the threshold voltage of the thin film transistor.

Optionally, the driving substrate 100 further includes a third insulation layer 18. The third insulation layer 18 is disposed on the at least one gate 16 and covers the active layer 14 and the first insulation layer 13. The second metal layer 17 is disposed on the third insulation layer 18.

The input electrode 171 blocks the semiconductor part 141 and the second conductive part 143. In a pattern of an orthographic projection of the driving substrate 100, the first conductive part 142 is at least partially disposed outside the input electrode 171.

In some embodiments, the input electrode 171 can be directly formed on the second conductive part 143 to omit the third insulation layer 18.

In this embodiment, because the input electrode 171 blocks the semiconductor part 141 and the second conductive part 143 and exposes the first conductive part 142, an ion doping treatment can be performed on the first conductive part 142 by using the input electrode 171 as a mask.

Optionally, a material of the second metal layer 17 may be selected from metal, such as chromium, copper, aluminum, gold, silver, zinc, molybdenum, tantalum, titanium, tungsten, manganese, nickel, iron, cobalt, alloy of any of the above-mentioned metal or alloy containing any of the above-mentioned metal. Moreover, the first metal layer 12 may be a single layer structure or a stacked structure of two or more layers.

Optionally, the second metal layer 17 further includes a binding pad 172 for binding and connecting to the light-emitting device.

Optionally, the driving substrate 100 further includes a fourth insulation layer 19 and a conductive layer 20. The fourth insulation layer 19 covers the second metal layer 17 and the third insulation layer 18. The conductive layer 20 is disposed on the fourth insulation layer 19 and includes a wiring. The wiring is electrically connected to the output electrode 121 and the binding pad 172.

Optionally, both of the third insulation layer 18 and the fourth insulation layer 19 may formed by multiple inorganic layers stacked in an alternate manner. For example, both of the first insulation layer 13 and the second insulation layer 15 may be a double layer formed by stacking inorganic layers including at least one of silicon oxide, silicon nitride, silicon nitride, aluminum oxide, magnesium oxide, and titanium oxide, or multiple layers formed by alternately stacking inorganic layers including at least one of silicon oxide, silicon nitride, silicon nitride, aluminum oxide, magnesium oxide, and titanium oxide. However, the present disclosure is not limited thereto. Both of the third insulation layer 18 and the fourth insulation layer 19 may be formed as a single inorganic layer including the above-mentioned insulation materials.

Moreover, in one or more embodiments, the third insulation layer 18 can be made of an organic insulation material such as polyimide.

Optionally, a material of the conductive layer 20 may include a metal oxide, such as ITO, IZO, or the like.

A preparation process of the driving substrate 100 in the first embodiment is as follows.

Step B11, as shown in FIG. 2, the patterned first metal layer 12, the first insulation layer 13, and a first conductive layer 14f are formed on the substrate 11 sequentially. The first conductive layer 14f includes the first conductive part 142 and the second conductive part 143. The material of the first conductive part 142 and the material of the second conductive part 143 are the same, and both are prepared using the same mask.

In some embodiments, the material of the first conductive part 142 and the material of the second conductive part 143 may be different.

Step B12, as shown in FIG. 3, the semiconductor part 141, the second insulation layer 15, and the gate 16 are formed on the substrate 11 sequentially. The semiconductor part 141 is formed between the first conductive part 142 and the second conductive part 143, and connected to the first conductive part 142 and the second conductive part 143 to form the active layer 14.

A top gate self-alignment process can be used to complete the patterning of the second insulation layer 15.

In some embodiments, the gate 16 at the top can be used as a mask to perform a conducting treatment on an exposed part of the first conductive part 142 and the second conductive part 143.

Step B13, as shown in FIG. 4, the third insulation layer 18 and the second metal layer 17 are formed on the substrate 11 sequentially. The third insulation layer 18 covers the gate 16, the active layer 14, and the first insulation layer 13. The second metal layer 17 includes the input electrode 171 and the binding pad 172.

Moreover, at step B13, the ion implantation process can be performed on the active layer 14 by using the input electrode 171 as a mask, which reduces the resistance value of the first conductive part 142.

Optionally, the doped ion includes, but is not limited to, hydrogenium (H), helium (He), boron (B), aluminum (Al), nitrogen (N), fluorine (F), phosphorus (P), argon (Ar), sulfur(S), and the like.

It should be noted that, before the ion implantation process, both of the surface resistivity of the first conductive part 142 and the surface resistivity of the second conductive part 143 range from 10 Ω/sq to 100 Ω/sq, such as 10 Ω/sq, 20 Ω/sq, 30 Ω/sq, 40 Ω/sq, 50 Ω/sq, 60 Ω/sq, 70 Ω/sq, 80 Ω/sq, 90 Ω/sq, or 100 Ω/sq.

After the ion doping process, the surface resistivity of the doped part of the first conductive part 142 ranges from 1 Ω/sq to 10 Ω/sq, such as 1 Ω/sq, 2 Ω/sq, 3 Ω/sq, 4 Ω/sq, 5 Ω/sq, 6 Ω/sq, 7 Ω/sq, 8 Ω/sq, 9 Ω/sq, or 10 Ω/sq.

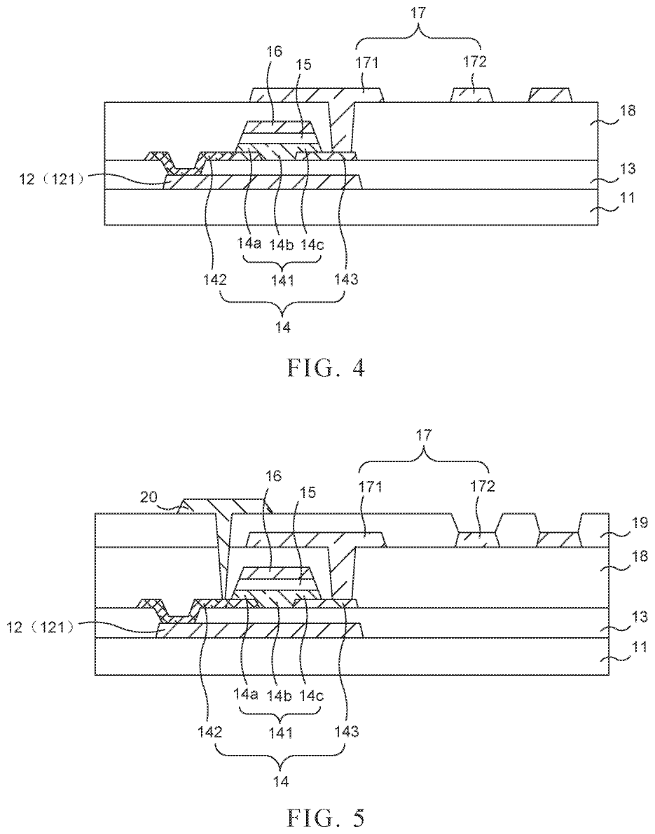

Step B14, as shown in FIG. 5, the fourth insulation layer 19 and the conductive layer 20 are formed on the second metal layer 17 sequentially. The fourth insulation layer 19 covers the second metal layer 17 and the third insulation layer 18.

Optionally, a conductive material layer can be formed by using a physical vapor deposition process, and patterned to form the conductive layer 20.

Thus, the preparation process of the driving substrate 100 of the first embodiment is completed.

Referring to FIG. 6, the driving substrate 100 in a second embodiment is different from the above-mentioned embodiment in that the at least one gate 16 includes a first gate 161 and a second gate 162. The first gate 161 is disposed on the second insulation layer 15. The second gate 162 is disposed in a same layer as the output electrode 121. The second gate 162 is disposed between the first insulation layer 13 and the substrate 11.

The first gate 161 covers the channel 14b. The second gate 162 is partially overlapped with the channel 14b. A part of the channel 14b that overlaps with the second gate 162 is connected to the first conductive part 142. A part of the channel 14b that does not overlap with the second gate 162 is connected to the second conductive part 143.

Compared to the first embodiment, the output electrode 121 of this embodiment is disposed outside the active layer 14. This second embodiment adopts the first gate 161 and the second gate 162 to simultaneously control the part of the active layer 14 close to the drain, which reduces the voltage drop of the drain region and improves the mobility.

Optionally, in a direction from the first conductive part 142 towards the second conductive part 143, a length of the part of the channel 14b overlapping with the second gate 162 accounts for one-fourth to one-half of the length of the channel 14b, which can suppress the influence of the hot carriers to a greater extent.

Optionally, the length of the part of the channel 14b overlapping with the second gate 162 may account for one-fourth, one-third, or one-half of the length of the channel 14b.

Referring to FIG. 7, the driving substrate 100 in a third embodiment is different from the first and second embodiments in that the first conductive part 142, the semiconductor part 141, and the second conductive part 143 are disposed in a same layer and integrally formed.

Compared to the above-mentioned two embodiments, the step for preparing the active layer 14 in this embodiment is simpler.

The driving substrate 100 in the third embodiment is described based on the second embodiment. A preparation process of the driving substrate 100 in the third embodiment is as follows.

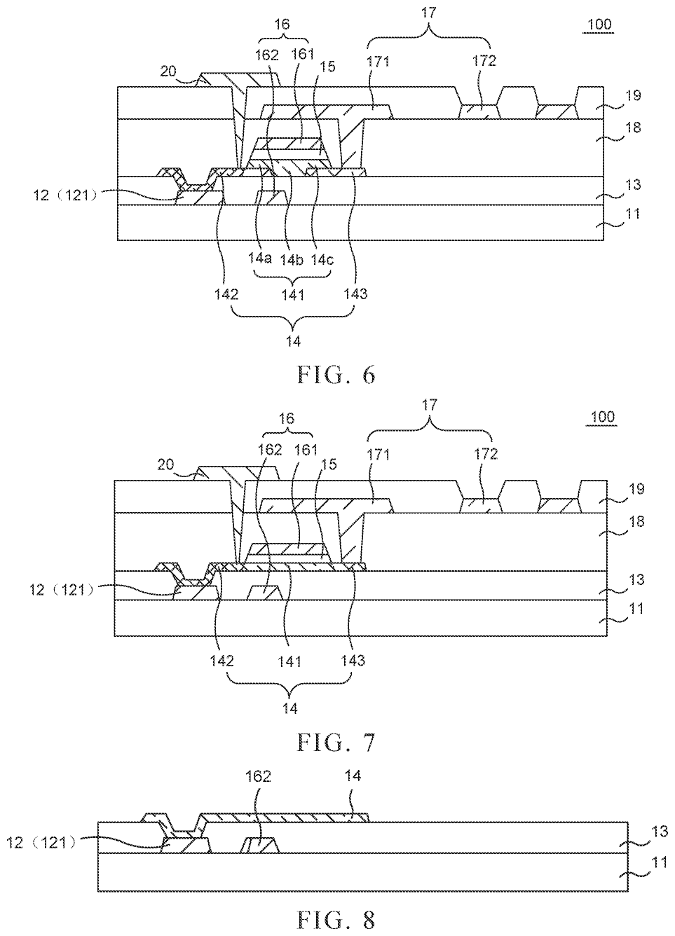

Step B21, as shown in FIG. 8, the patterned first metal layer 12, the first insulation layer 13, and the active layer 14 are formed on the substrate 11 sequentially. The first metal layer 12 includes the output electrode 121 and the second gate 162.

The first insulation layer 13 covers the first metal layer 12 and the substrate 11.

At step B21, the material of the active layer 14 is metal oxide. For example, the metal oxide may include at least one of indium gallium zinc oxide, indium zinc oxide, zinc tin oxide, indium gallium oxide, indium tin oxide, indium zirconium oxide, indium zirconium zinc oxide, indium zirconium tin oxide, indium zirconium gallium oxide, indium aluminum oxide, indium zinc aluminum oxide, indium tin aluminum oxide, indium aluminum gallium oxide, indium tantalum oxide, indium tantalum zinc oxide, indium tantalum tin oxide, indium tantalum gallium oxide, indium germanium oxide, indium germanium zinc oxide, indium germanium tin oxide, indium germanium gallium oxide, titanium indium zinc oxide, and hafnium indium zinc oxide.

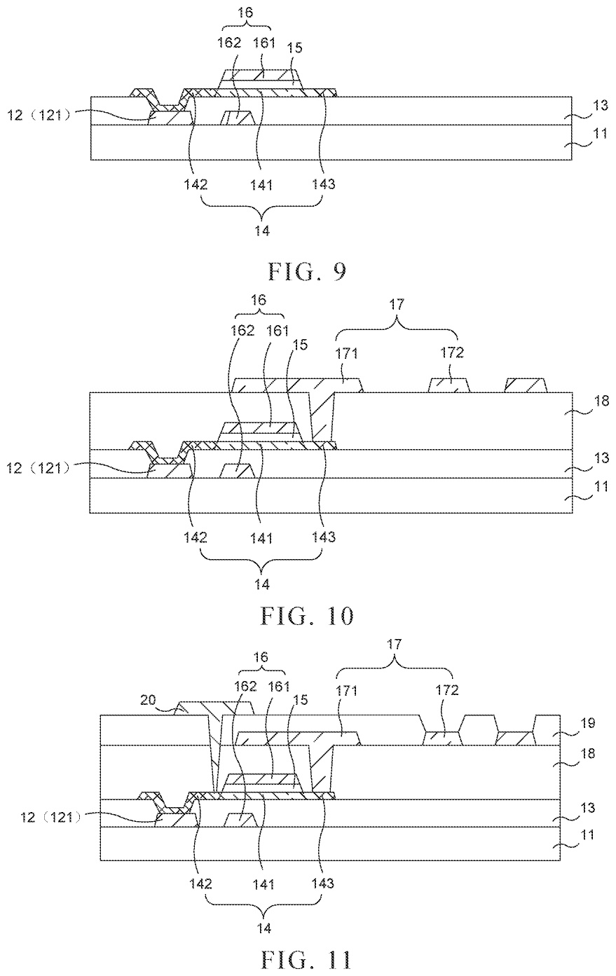

Step B22, as shown in FIG. 9, the second insulation layer 15 and the first gate 161 are formed on the active layer 14 sequentially. The second insulation layer 15 is patterned by using a self-alignment process of the first gate 161, and the first gate 161 is used as the mask to perform a conducting treatment on the non-channel part of the active layer 14, so as to form the first conductive part 142, the semiconductor part 141 (containing the channel), and the second conductive part 143.

Step B23, as shown in FIG. 10, the third insulation layer 18 and the second metal layer 17 are formed on the substrate 11 sequentially. The third insulation layer 18 covers the gate 16, the active layer 14, and the first insulation layer 13. The second metal layer 17 includes the input electrode 171 and the binding pad 172.

Moreover, at step B23, the ion implantation process is performed on the first conductive part 142 of the active layer 14 by using the input electrode 171 as the mask, which can reduce the resistance value of the first conductive part 142.

Optionally, the doped ion includes but is not limited to, hydrogenium (H), helium (He), boron (B), aluminum (Al), nitrogen (N), fluorine (F), phosphorus (P), argon (Ar), sulfur(S), and the like.

Step B24, as shown in FIG. 11, the fourth insulation layer 19 and the conductive layer 20 are formed on the second metal layer 17 sequentially. The fourth insulation layer 19 covers the second metal layer 17 and the third insulation layer 18.

Optionally, a conductive material layer is formed by using a physical vapor deposition process, and patterned to form the conductive layer 20.

Thus, the preparation process of the driving substrate 100 of the third embodiment is completed.

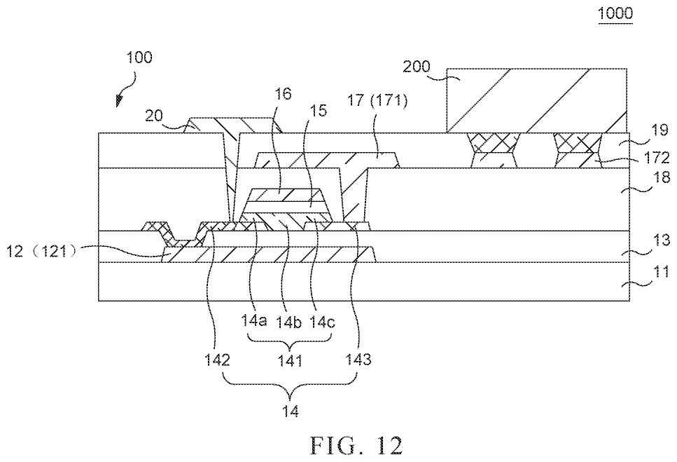

Referring to FIG. 12, accordingly, embodiments of the present disclosure further provide a display panel 1000, which includes a light-emitting device 200 and the driving substrate 100 as described in any of the above-mentioned embodiments. The light emitting device 200 is disposed on the driving substrate 100, and the output electrode 121 is electrically connected to the light emitting device 200.

Optionally, the light-emitting device 200 can be a sub-millimeter light-emitting diode (Mini LED), a micro light-emitting diode (Micro LED), or an organic light-emitting diode (OLED).

The structure of the driving substrate 100 of the display panel 1000 in this embodiment is similar to or the same as the structure of the driving substrate 100 in any of the above-mentioned embodiments, and will not be described here.

The driving substrate 100 of the display panel 1000 in this embodiment includes the substrate 11, the first metal layer 12, the first insulation layer 13, the active layer 14, the second insulation layer 15, the gate 16, and the second metal layer 17.

The first metal layer 12 includes the output electrode 121 for electrically connecting the light emitting device. The first insulation layer 13 is disposed on the first metal layer 12 and covers the substrate 11. The active layer 14 is disposed on the first insulation layer 13.

The active layer 14 includes the semiconductor part 141, the first conductive part 142, and the second conductive part 143. The first conductive part 142 is connected to a side of the semiconductor part 141 close to the output electrode 121, the second conductive part 143 is connected to a side of the semiconductor part 141 away from the output electrode 121, and the first conductive part 142 is connected to the output electrode 121. The surface resistivity of the first conductive part 142 is less than the surface resistivity of the second conductive part 143.

The second insulation layer 15 is disposed on the semiconductor part 141. The gate 16 is disposed on the second insulation layer 15 and overlapping with the semiconductor part 141. The second metal layer 17 includes the input electrode 171 connected to the second conductive part 143. The input electrode 171, the output electrode 121, the active layer 14, and the gate 16 are used to form the thin film transistor.

Due to the fact that the surface resistivity of the first conductive part 142 is less than the surface resistivity of the second conductive part 143, the resistance of the part of the active layer 14 close to the output electrode 121 is less than the resistance of the part of the active layer 14 close to the input electrode 171, which decreases the voltage drop of the part of the active layer 14 close to the output electrode 121, thereby reducing the impact of the hot carriers on the threshold voltage.

The driving substrate and the display device provided by the embodiments of the present disclosure are described in detail. In this context, specific embodiments are adopted to illustrate a principle and implementation modes of the present disclosure. The description of the above-mentioned embodiments is only used to help understand methods and a core idea of the present disclosure. At the same time, for those skilled in the art, according to the idea of the present disclosure, there will be changes in specific implementation modes and a scope of the present disclosure. In conclusion, contents of the specification should not be interpreted as a limitation of the present disclosure.

1. A driving substrate, comprising:
a substrate;
a first metal layer comprising an output electrode, wherein the output electrode is used to electrically connect a light-emitting device;
a first insulation layer disposed on the first metal layer and covering the substrate;
an active layer disposed on the first insulation layer and comprising a semiconductor part, a first conductive part, and a second conductive part, wherein the first conductive part is connected to a side of the semiconductor part close to the output electrode, the second conductive part is connected to a side of the semiconductor part away from the output electrode, and the first conductive part is connected to the output electrode; wherein a surface resistivity of the first conductive part is less than a surface resistivity of the second conductive part;
a second insulation layer disposed on the semiconductor part;
at least one gate disposed on the second insulation layer and overlapped with the semiconductor part; and
a second metal layer comprising an input electrode, wherein the input electrode is connected to the second conductive part, and the input electrode, the output electrode, the active layer, and the gate are used to form a thin film transistor.

2. The driving substrate of claim 1, wherein a concentration of a doped ion in the first conductive part is greater than a concentration of a doped ion in the second conductive part.

3. The driving substrate of claim 2, wherein a material of the first conductive part comprises a metal oxide and the doped ion, and the doped ion is doped in the metal oxide; wherein a material of the second conductive part comprises at least the metal oxide.

4. The driving substrate of claim 3, wherein the material of the second conductive part further comprises the doped ion.

5. The driving substrate of claim 1, wherein the at least one gate comprises a first gate and a second gate, the first gate is disposed on the second insulation layer, the second gate is disposed in a same layer as the output electrode, and the second gate is disposed between the first insulation layer and the substrate; and
the semiconductor part comprises a channel, the first gate covers the channel, and the second gate is disposed partially overlapping with the channel; wherein a part of the channel overlapping with the second gate is connected to the first conductive part, and a part of the channel not overlapping with the second gate is connected to the second conductive part.

6. The driving substrate of claim 5, wherein a length of the part of the channel overlapping with the second gate accounts for one-fourth to one-half of a length of the channel in a direction from the first conductive part towards the second conductive part.

7. The driving substrate of claim 5, wherein the first conductive part, the semiconductor part, and the second conductive part are disposed in a same layer and integrally formed.

8. The driving substrate of claim 5, wherein the first conductive part and the second conductive part are disposed in a same layer and spaced apart, wherein the semiconductor part further comprises a first lap-joint part and a second lap-joint part, the first lap-joint part is connected to a side of the first conductive part away from the substrate, and the second lap-joint part is connected to a side of the second conductive part away from the substrate; wherein an end of the channel is connected to the first lap-joint part and the first conductive part, and another end of the channel is connected to the second lap-joint part and the second conductive part.

9. The driving substrate of claim 1, wherein the output electrode is overlapped with the active layer.

10. The driving substrate of claim 8, wherein a part of the first conductive part overlapping with the first lap-joint part has a first resistance value, a part of the first conductive part not overlapping with the first lap-joint part has a second resistance value, and the first resistance value is greater than the second resistance value.

11. The driving substrate of claim 1, wherein the driving substrate further comprises a third insulation layer, and the third insulation layer is disposed on the at least one gate and covers the active layer and the first insulation layer; wherein the second metal layer is disposed on the third insulation layer; and
the input electrode blocks the semiconductor part and the second conductive part, wherein in a pattern of an orthographic projection of the driving substrate, the first conductive part is at least partially disposed outside the input electrode.

12. A display panel comprising a light-emitting device and a driving substrate, wherein the light-emitting device is disposed on the driving substrate, and an output electrode is provided to be electrically connected to the light-emitting device; wherein the driving substrate comprises:
a substrate;
a first metal layer comprising the output electrode;
a first insulation layer disposed on the first metal layer and covering the substrate;
an active layer disposed on the first insulation layer and comprising a semiconductor part, a first conductive part, and a second conductive part, wherein the first conductive part is connected to a side of the semiconductor part close to the output electrode, the second conductive part is connected to a side of the semiconductor part away from the output electrode, and the first conductive part is connected to the output electrode; wherein a surface resistivity of the first conductive part is less than a surface resistivity of the second conductive part;
a second insulation layer disposed on the semiconductor part;
at least one gate disposed on the second insulation layer and overlapped with the semiconductor part; and
a second metal layer comprising an input electrode, wherein the input electrode is connected to the second conductive part, and the input electrode, the output electrode, the active layer, and the gate are used to form a thin film transistor.

13. The display panel of claim 12, wherein a concentration of a doped ion in the first conductive part is greater than a concentration of a doped ion in the second conductive part.

14. The display panel of claim 13, wherein a material of the first conductive part comprises a metal oxide and the doped ion, and the doped ion is doped in the metal oxide; wherein a material of the second conductive part comprises at least the metal oxide.

15. The display panel of claim 14, wherein the material of the second conductive part further comprises the doped ion.

16. The display panel of claim 12, wherein the at least one gate comprises a first gate and a second gate, the first gate is disposed on the second insulation layer, the second gate is disposed in a same layer as the output electrode, and the second gate is disposed between the first insulation layer and the substrate; and
the semiconductor part comprises a channel, the first gate covers the channel, and the second gate is disposed partially overlapping with the channel; wherein a part of the channel overlapping with the second gate is connected to the first conductive part, and a part of the channel not overlapping with the second gate is connected to the second conductive part.

17. The display panel of claim 16, wherein a length of the part of the channel overlapping with the second gate accounts for one-fourth to one-half of a length of the channel in a direction from the first conductive part towards the second conductive part.

18. The display panel of claim 16, wherein the first conductive part, the semiconductor part, and the second conductive part are disposed in a same layer and integrally formed.

19. The display panel of claim 16, wherein the first conductive part and the second conductive part are disposed in a same layer and spaced apart, wherein the semiconductor part further comprises a first lap-joint part and a second lap-joint part, the first lap-joint part is connected to a side of the first conductive part away from the substrate, and the second lap-joint part is connected to a side of the second conductive part away from the substrate; wherein an end of the channel is connected to the first lap-joint part and the first conductive part, and another end of the channel is connected to the second lap-joint part and the second conductive part.

20. The display panel of claim 12, wherein the output electrode is overlapped with the active layer.
